(19) United States
(12) Patent Application Publication
(10) Pub. No.: US 2006/0186428 A1
(43) Pub. Date: Aug. 24, 2006

(54) Light emitting device with enhanced encapsulant adhesion using siloxane material and method for fabricating the device

(76) Inventors: Kheng Leng Tan, Penang (MY); Kee Yean Ng, Penang (MY); Shir Li Ng, Penang (MY); Wen Ya Ou, Penang (MY)

Correspondence Address: AGILENT TECHNOLOGIES, INC.;INTELLECTUAL PROPERTY ADMINISTRATION, LEGAL DEPT., M/S DU404, P.O. BOX 7599, LOVELAND, CO, 80537-0599, US

(21) Appl. No.: 11/064,064

(22) Filed: Feb. 23, 2005

(51) Int. Cl. H01L 21/00; H01L 33/00

(52) U.S. Cl. 257/100; 438/25; 257/E33.059

(57) ABSTRACT

A light emitting device and method for fabricating the device utilizes an adhesive layer of siloxane material to enhance the adhesion of an encapsulant to a light source, one or more leadframes and/or a reflector cup surface. The siloxane layer can be used in different types of light emitting devices, such as lead frame-mounted light emitting diodes (LEDs) and surface mount LEDs with or without reflector cups.

### BACKGROUND OF THE INVENTION

Light emitting devices with optically transparent encapsulant, such as light emitting diodes (LEDs), are comprised of multiple components, which are packaged or integrated into a single unit. For an LED, these components include an LED die, one or more bond wires, a mounting structure (which may be a leadframe) and the encapsulant. The optical performance of the LED depends on the integrity of these packaged components. Thus, the integrity of the packaged components must be maintained to achieve proper and reliable optical performance throughout the operating lifetime of the LED.

One of the factors that can compromise the integrity of the packaged LED components is non-uniform thermal expansion of the components. The coefficient of thermal expansion (CTE) of the encapsulant is much higher than that of the LED die, the bond wire(s) and the mounting structure. Due to this CTE mismatch, the encapsulant often becomes delaminated from the LED die and the mounting structure over time, which subsequently leads to decrease in optical performance or even malfunction of the LED.

A conventional technique to reduce the risk of encapsulant delamination involves plasma etching the surfaces of the LED die and the mounting structure to alter the surface properties for adhesion enhancement. A disadvantage of this technique is that the plasma-etched surfaces have a limited workable shelf life. Thus, plasma-etched components may have to be re-etched if the components are not used within an acceptable period of time. Another disadvantage of this technique is the cost associated with this additional process. Furthermore, not all LED components can be plasma etched which limits the use of this technique to certain types of LEDs.

In view of the above-described disadvantages, there is a need for a light emitting device with enhanced encapsulant adhesion and method for fabricating the device which alleviates these disadvantages.

### SUMMARY OF THE INVENTION

A light emitting device and method for fabricating the device utilizes an adhesive layer of siloxane material to enhance the adhesion of an encapsulant to a light source, one or more leadframes and/or a reflector cup surface. The siloxane layer can be used in different types of light emitting devices, such as lead frame-mounted light emitting diodes (LEDs) and surface mount LEDs with or without reflector cups.

A light emitting device in accordance with an embodiment of the invention comprises a mounting structure having a surface, a light source coupled to the surface of the mounting structure, an adhesive layer of siloxane material over the light source, and an encapsulant coupled to the light source via the adhesive layer of siloxane material, which provides adhesion between the encapsulant and the light source.

A method for fabricating a light emitting device with an encapsulant in accordance with an embodiment of the invention comprises attaching a light source to a surface of a mounting structure, forming an adhesive layer of siloxane material over the light source, and forming the encapsulant over the adhesive layer of siloxane material, which provides adhesion between the light source and the encapsulant.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a diagram of a leadframe-mounted light emitting diode (LED) with a reflector cup in accordance with an embodiment of the invention.

FIGS. 2A-2B illustrate the process for fabricating the LED of FIG. 1 in accordance with an embodiment of the invention.

FIG. 3 is a diagram of a leadframe-mounted LED without a reflector cup in accordance with an embodiment of the invention.

FIG. 4 is a diagram of a surface mount LED with a reflector cup in accordance with an embodiment of the invention.

FIG. 5 is a diagram of a surface mount LED without a reflector cup in accordance with an embodiment of the invention.

FIG. 6 is a process flow diagram of a method for fabricating a light emitting device, such as an LED, in accordance with an embodiment of the invention.

### DETAILED DESCRIPTION

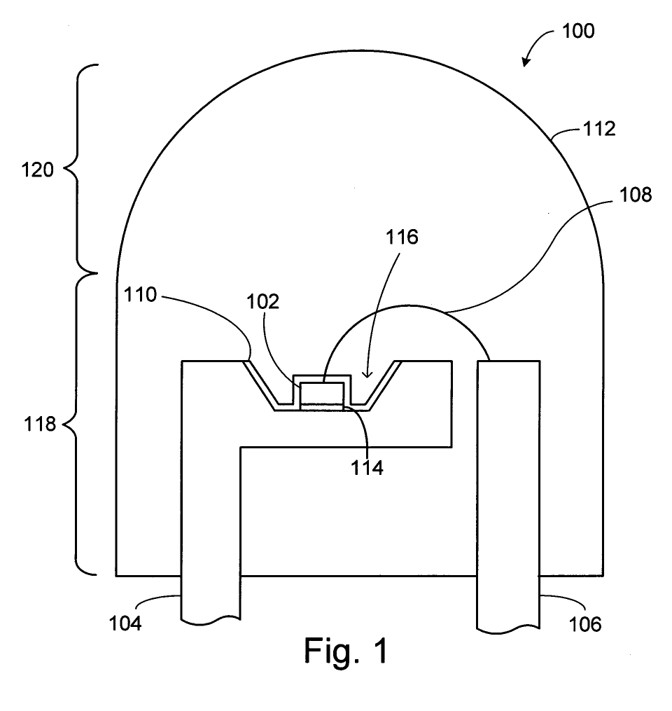

With reference to FIG. 1, a leadframe-mounted light emitting diode (LED) 100 in accordance with an embodiment of the invention is described. The LED 100 includes an LED die 102, leadframes 104 and 106, a bond wire 108, an adhesive layer 1 10 of siloxane material and an encapsulant 112. As described in more detail below, the adhesive layer 110 of siloxane material enhances the adhesion of the encapsulant 112 to the LED die 102 and the leadframe 104, which reduces the risk of encapsulant delamination over time. Consequently, the LED 100 is more reliable than conventional LEDs and has a reduced chance of performance degradation and/or malfunction.

The LED die 102 is a semiconductor chip that generates light of a particular peak wavelength. Thus, the LED die 102 is a light source of the LED 100. Although the LED 100 is shown in FIG. 1 as having only a single LED die, the LED may include multiple LED dies. The LED die 102 is attached or mounted on the upper surface of the leadframe 104 using an adhesive material 114, and electrically connected to the other leadframe 106 via the bond wire 108. The leadframes 104 and 106 are made of metal, and thus, are electrically conductive. The leadframes 104 and 106 provide the electrical power needed to drive the LED die 102.

In this embodiment, the leadframe 104 includes a depressed region 116 at the upper surface, which forms a reflector cup in which the LED die 102 is mounted. Since the LED die 102 is mounted on the leadframe 104, the leadframe 104 can be considered to be a mounting structure for the LED die. The surface of the reflector cup 116 may be reflective so that some of the light generated by the LED die 102 is reflected away from the leadframe 104 to be emitted from the LED 100 as useful output light.

The LED die 102 is encapsulated in the encapsulant 112, which is a medium for the propagation of light from the LED die. The encapsulant 112 includes a main section 118 and an output section 120. In this embodiment, the output section 120 of the encapsulant 112 is dome-shaped to function as a lens. Thus, the light emitted from the LED 100 as output light is focused by the dome-shaped output section 120 of the encapsulant 112. However, in other embodiments, the output section 120 of the encapsulant 112 may be horizontally planar. The encapsulant 112 is made of an optically transparent substance so that light from the LED die 102 can travel through the encapsulant and be emitted out of the output section 120 as output light. As an example, the encapsulant 112 can be made of polymer (formed from liquid or semisolid precursor material such as monomer), epoxy, silicone, glass or a hybrid of silicone and epoxy.

As shown in FIG. 1, the adhesive layer 110 of siloxane material is located between the LED die 102 and the encapsulant 112, and between the reflector cup 116 and the encapsulant. Thus, in the illustrated embodiment, the siloxane layer 110 covers the LED die 102 and the entire reflector cup surface. However, in other embodiments, the siloxane layer 110 may cover the LED die 102, and/or a portion of the reflector cup 116 of the leadframe 104. The siloxane layer 110 may even cover some or all of the upper surface of the leadframe 104 outside of the reflector cup 116. As an example, the thickness of the siloxane layer 110 may be in the micron range.

Siloxane material exhibits good adhesive property to both metal and plastic surfaces. Thus, the siloxane layer 110 is used in the LED 100 as an adhesive to bond the encapsulant 112 to the LED die 102 and/or the mounting structure, i.e., the leadframe 104. In an exemplary embodiment, the siloxane layer 110 is a layer of spin-on-glass (SOG) material and/or silane material. Although the siloxane layer 110 is shown as being a single layer in FIG. 1, the siloxane layer may comprise multiple layers of siloxane material.

Siloxane material such as SOG material is usually used as a dielectric intermediate layer in silicon wafers for passivation purpose. It is also used for planarization during fabrication of integrated circuits using multilevel metal techniques. The siloxane material can be doped with different materials for optical, mechanical, thermal or adhesion purpose. Another siloxane material of interest is silane material, which is normally added into the encapsulation material to improve adhesion between interfaces, which can be any interface between a polymer surface and another surface, such as metal, glass, polymer, or inorganic surface.

In the LED 100, the siloxane layer 110 is used as an adhesive intermediate layer between the encapsulant 112 and the LED die 102 and/or between the encapsulant and the leadframe 104. Unlike the prior art of using plasma etching to improve adhesion of encapsulant, there is no shelf life to the siloxane layer 110, which means that the LED 100 without the encapsulant 112 can be stored for a long period of time. Thus, the use of the siloxane layer 110 is more user-friendly in the production environment of LEDs than the prior art of plasma etching. Furthermore, the production cost associated with the siloxane layer 110 is very low when compared to plasma etching, and the siloxane layer 110 can be applied to all types of LEDs. Thus, the use of the siloxane layer 110 is a better solution than plasma etching in producing an LED that will perform properly and reliably in a wide variety of operational and environmental conditions.

An additional advantage of the siloxane layer 110 is that the layer blocks ultraviolet (UV) light. Thus, the siloxane layer 110 can serve as a protective barrier between the LED die 102 and the encapsulant 112 to prevent UV or near UV light emitted from the LED die from damaging the encapsulant.

For epoxy encapsulant, UV light degrades the encapsulant by turning the encapsulant yellowish in color, which decreases the light output from the encapsulant. Thus, the siloxane layer 110 can significantly reduce UV damage to the encapsulant 112, which reduces the light output loss due to UV degradation of the encapsulant. This is especially important if the LED 100 is a blue-emitting or white-emitting LED, since such an LED includes an LED die that generates significant amount of light in the UV or near UV wavelength range.

The siloxane layer 110 may include additives such as antioxidants (Phenolic Stabilizers, Organophosphorus compounds, Lactone and Hydorxylamine) and light stabilizers (Hindered Amide Light Stabilizers) to improve the optical properties of the siloxane layer. The siloxane layer 110 may also include phosphors, dyes (organic or inorganic) and/or laser dyes, which can be used to convert some or virtually all of the light generated by the LED die 102 to produce an output light of a desired wavelength characteristic, e.g., white output light.

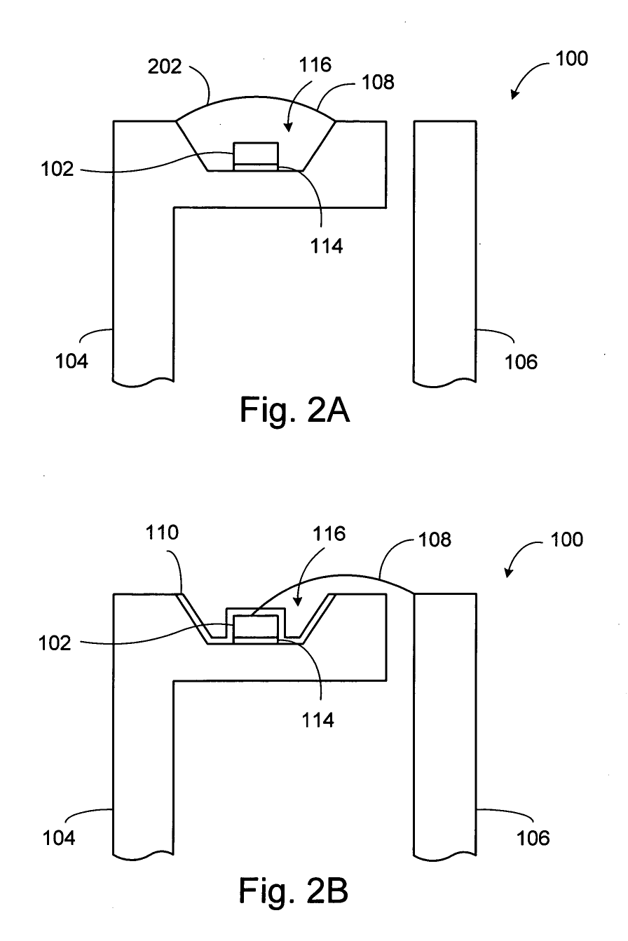

The process for fabricating the LED 100 in accordance with an embodiment of the invention is now described with reference to FIGS. 2A and 2B, as well as FIG. 1. This process is performed at the device level. First, the LED die 102 is attached to the mounting structure, i.e., the leadframe 104, using the adhesive material 114. The LED die 102 is then electrically connected to the other leadframe 106 by the bond wire 108. In order to form the siloxane layer 110, a siloxane material (e.g., SOG or silane) is mixed with a fluid. As an example, the siloxane material is mixed into a carrier or diluted by one or more solvents, such as alcohols, ketones and acetates, at certain ratios. At this point, other additives may be selectively added to the mixture, such as antioxidant additives, light stabilizer additives, phosphors, inorganic dyes, organic dyes, and laser dyes. The mixture 202 is then dispensed into the reflector cup 116, as illustrated in FIG. 2A. The LED 100 without the encapsulant 112 is then baked at around 250 degrees Celsius to take off the carrier or solvents, leaving a very thin layer 110 of siloxane material, as illustrated in FIG. 2B. The encapsulant 112 is then formed over the LED die 102 to produce the finished LED 100, as shown in FIG. 1.

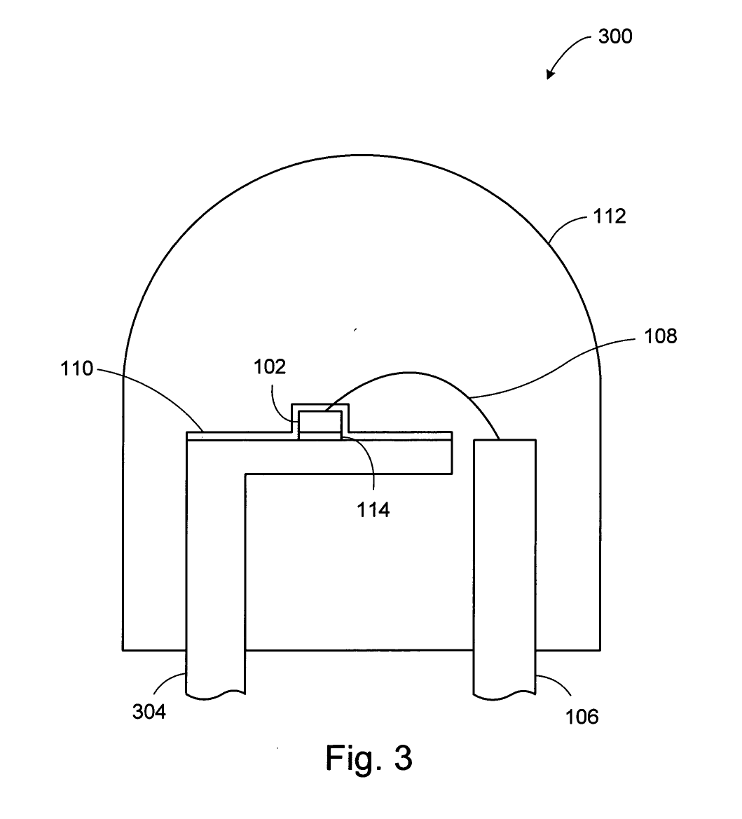

Turning now to FIG. 3, a leadframe-mounted LED 300 in accordance with another embodiment of the invention is shown. The same reference numerals used in FIG. 1 are used to identify similar elements in FIG. 3. In this embodiment, the LED 300 includes a mounting structure, i.e., a leadframe 304, which does not have a reflector cup. Thus, the upper surface of the leadframe 304 on which the LED die 102 is attached is substantially planar. The siloxane layer 110 covers the LED die 102 and the upper surface of the leadframe 304. In other embodiments, the siloxane layer 110 may cover the LED die 102 and/or a portion of the upper surface of the leadframe 304.

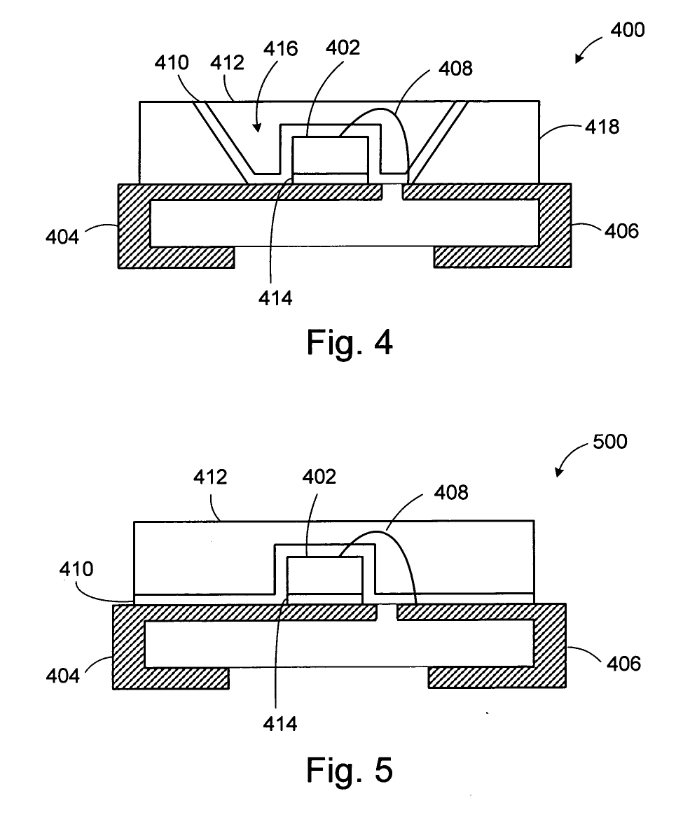

Turning now to FIG. 4, a surface mount LED 400 in accordance with an embodiment of the invention is shown. The LED 400 includes an LED die 402, leadframes 404 and 406, a bond wire 408, an adhesive layer 410 of siloxane material and an encapsulant 412. The LED die 402 is attached to the leadframe 404 using an adhesive material 414. The bond wire 408 is connected to the LED die 402 and the leadframe 406 to provide an electrical connection. The LED 400 further includes a reflector cup 416 formed on a poly(p-phenyleneacetylene) (PPA) housing or a printed circuit board 418. The encapsulant 412 is located in the reflector cup 416. In this embodiment, the siloxane layer 410 covers the LED die 402, exposed portions of the leadframes 404 and 406, and the surface of the reflector cup 416. Thus, in this embodiment, the siloxane layer 410 provides adhesion of the encapsulant 412 to the LED die 402, the leadframes 404 and 406 and the reflector cup 416. However, in other embodiments, the siloxane layer 410 may selectively cover the LED die 402, the leadframe 404, the leadframe 406, and/or the reflector cup 416.

Turning now to FIG. 5, a surface mount LED 500 in accordance with another embodiment of the invention is shown. The same reference numerals used in FIG. 4 are used to identify similar elements in FIG. 5. In this embodiment, the LED 500 does not include a reflector cup. Consequently, the siloxane layer 410 covers the LED die 402 and the upper surfaces of the leadframes 404 and 406. Thus, in this embodiment, the siloxane layer 410 provides adhesion of the encapsulant 412 to the LED die 402 and the leadframes 404 and 406. However, in other embodiments, the siloxane layer 410 may selectively cover the LED die 402, the leadframe 404 and/or the leadframe 406.

Although different embodiments of the invention have been described herein as being LEDs, other types of light emitting devices, such as semiconductor lasing devices, in accordance with the invention are possible. In fact, the invention can be applied to any light emitting device that has an attached encapsulant or any type of optically transparent medium.

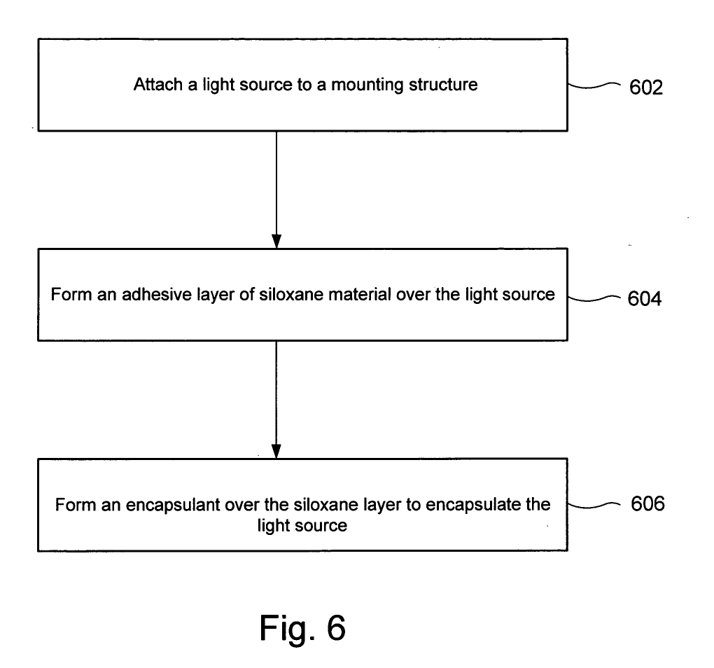

A method for fabricating a light emitting device, such as an LED, in accordance with an embodiment of the invention is described with reference to the process flow diagram of FIG. 6. At block 602, a light source is attached to a mounting structure. As an example, the light source may be an LED die and the mounting structure may be a leadframe. Next, at block 604, an adhesive layer of siloxane material is formed over the light source. Next, at block 606, an encapsulant is formed over the siloxane layer to encapsulate the light source. Thus, the siloxane layer is situated between the light source and the encapsulant to enhance the adhesion between the encapsulant and the light source.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A light emitting device comprising:
a mounting structure having a surface;
a light source coupled to said surface of said mounting structure;
an adhesive layer of siloxane material over said light source; and
an encapsulant coupled to said light source via said adhesive layer of siloxane material, said adhesive layer of siloxane material providing adhesion between said encapsulant and said light source.

2. The device of claim 1 wherein said light source includes a light emitting diode die.

3. The device of claim 1 wherein said adhesive layer of siloxane material includes at least one of spin-on-glass material and silane material.

4. The device of claim 1 wherein said adhesive layer of siloxane material is on at least a portion of said surface of said mounting structure.

5. The device of claim 1 wherein said adhesive layer of siloxane material is on at least a portion of a recessed region of said mounting structure.

6. The device of claim 1 further comprising a reflector cup on said mounting structure, and wherein said adhesive layer of siloxane material is on at least a portion of said reflector cup.

7. The device of claim 1 wherein said adhesive layer of siloxane material includes at least one of antioxidant additive and light stabilizer additive.

8. The device of claim 1 wherein said adhesive layer of siloxane material includes at least one of organic die, inorganic dye, phosphor and laser dye.

9. A method for fabricating a light emitting device with an encapsulant, said method comprising:
attaching a light source to a surface of a mounting structure;
forming an adhesive layer of siloxane material over said light source; and
forming said encapsulant over said adhesive layer of siloxane material, said adhesive layer of siloxane material providing adhesion between said encapsulant and said light source.

10. The method of claim 9 wherein said forming of said adhesive layer of siloxane material includes:
mixing said siloxane material with a fluid to produce a mixture;
dispensing said mixture onto said light source attached to said mounting structure; and
heating said mixture on said light source to form said adhesive layer of siloxane material on said light source.

11. The method of claim 10 wherein said mixing includes adding at least one of antioxidant additive and light stabilizer additive into said mixture.

12. The device of claim 10 wherein said mixing includes adding at least one of organic die, inorganic dye, phosphor and laser dye into said mixture.

13. The method of claim 9 wherein said adhesive layer of siloxane material includes at least one of spin-on-glass material and silane material.

14. The method of claim 9 wherein said forming of said adhesive layer of siloxane material includes forming said adhesive layer of siloxane material over at least a portion of said surface of said mounting structure.

15. The method of claim 9 wherein said forming of said adhesive layer of siloxane material includes forming said adhesive layer of siloxane material over at least a portion of a reflector cup in which said light source is positioned.

16. A light emitting device comprising:
a leadframe having a surface;
a light emitting diode die attached to said surface of said leadframe;
an adhesive layer of siloxane material on said light emitting diode die; and
an encapsulant coupled to said light source via said layer of siloxane material, said adhesive layer of siloxane material providing adhesion between said encapsulant and said light emitting diode die.

17. The device of claim 16 wherein said adhesive layer of siloxane material includes at least one of spin-on-glass material and silane material.

18. The device of claim 16 wherein said adhesive layer of siloxane material is on at least a portion of said surface of said leadframe.

19. The device of claim 16 wherein said adhesive layer of siloxane material is on at least a portion of a reflector cup in which said light emitting diode die is positioned.

20. The device of claim 16 wherein said adhesive layer of siloxane material includes an element selected from a group consisting of antioxidant additive, light stabilizer additive, organic die, inorganic dye, phosphor and laser dye.
